(19) United States
(12) Patent Application Publication
(10) Pub. No.: US 2026/0118704 A1
(43) Pub. Date: Apr. 30, 2026

(54) MODULATED LASER BIAS AND DRIVER CIRCUITS

(71) Applicant: MACOM Technology Solutions Holdings, Inc., Lowell, MA (US)

(72) Inventors: Atul Krishna Gupta, Mission Viejo, CA (US); Ryan Suresh Latchman, Irvine, CA (US)

(21) Appl. No.: 19/373,228

(22) Filed: Oct. 29, 2025

Related U.S. Application Data
(60) Provisional application No. 63/713,474, filed on Oct. 29, 2024.

(51) Int. Cl. G02F 1/01; G02F 1/015; H01S 5/06

(52) U.S. Cl. CPC G02F 1/0121; G02F 1/0157; H01S 5/0614

(57) ABSTRACT

Bias and driver circuits for modulated lasers are described. An example bias and driver circuit includes a laser, an electro-absorption optical modulator configured to modulate light output from the laser, a driver, and a power converter. The electro-absorption optical modulator is coupled between a float node and a ground node in the bias and driver circuit. The driver has an output coupled to the electro-absorption optical modulator, and the driver is configured to control the electro-absorption optical modulator to modulate the light output from the laser. The power converter is configured to maintain the float node at a potential greater than the ground node. The bias and driver circuits provide an alternative circuit arrangement for modulated lasers, including electro-absorption modulated lasers (EMLs), and are designed to operate without the use of ferrite beads or inductors in filter networks that would otherwise be coupled between the drivers and the modulators.

### CROSS REFERENCE TO RELATED APPLICATIONS

This application claims the benefit of and priority to U.S. Provisional Application No. 63/713,474, titled “MODULATED LASER BIAS AND DRIVER CIRCUITS,” filed Oct. 29, 2024, the entire contents of which is hereby incorporated herein by reference.

### BACKGROUND

The amount of data processed by computing environments, network switching environments, and related systems continues to increase. Data centers can include hundreds or thousands of networking and computing systems. The systems are interconnected by optical cables, copper cables, and various connectors, adapters, and terminations between them. The data throughput of the interconnection systems is high and increasing. A range of different interconnect solutions, including optical interconnect solutions that transmit data using laser diodes, are being adopted for data interconnection applications.

An optical communications link can be realized as a single end-to-end optical circuit. An optical fiber is one example of an optical link. In many cases, optical fibers are flexible, transparent fibers made by drawing glass or plastic to a suitably small diameter. Optical fibers can be used as a means to transmit light in fiber-optic communications and to permit data transmission over relatively longer distances and at relatively higher bandwidths than wire cables. Optical fibers are also preferable in some cases because signals travel along them with less loss and without electromagnetic interference.

Optical devices can be integrated with electronic components using semiconducting materials and semiconductor manufacturing techniques in silicon photonics, as one example approach. Silicon photonics devices can be relied upon to communicate data between optical transmitters and receivers over optical communications links. In an optical transmitter, data is used to modulate light, such as that produced by a light or laser emitting diode, and the modulated light can be transmitted to an optical receiver over waveguides, fiber optic cables, etc. Modulated light streams (e.g., optical data streams) are more suitable for long distance, low loss data transmission as compared to data transmitted in the electrical domain.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

Bias and driver circuits for modulated lasers are described. An example bias and driver circuit includes a laser, an electro-absorption optical modulator configured to modulate light output from the laser, a driver, and a power converter. The electro-absorption optical modulator is coupled between a float node and a ground node in the bias and driver circuit. The driver has an output coupled to the electro-absorption optical modulator, and the driver is configured to control the electro-absorption optical modulator to modulate the light output from the laser. The power converter is configured to maintain the float node at a potential greater than the ground node.

In other aspects, the laser is coupled and biased between the float node, at one end of the laser, and an output of a second power converter at the other end. The power converter can include a DC/DC boost converter having an output connected to the float node, and the second power converter can include a DC/DC floating converter coupled between the float node and the output of the second converter. The output of the DC/DC boost converter sets a voltage potential at the float node in the bias and driver circuit. In still other aspects, the driver output can be directly coupled to the electro-absorption optical modulator. The driver may also be configured to control the modulator based on drive potentials that are greater than the ground node and less than the float node.

The bias and driver circuit can also include a resistor and a capacitor, where the electro-absorption optical modulator, the resistor, and the capacitor are electrically connected in series between the float node and the ground node. A second capacitor can be coupled in parallel with the series arrangement between the float node and the ground node. In some cases, the series arrangement includes a first node located between the electro-absorption optical modulator and the resistor and a second node located between the resistor and the capacitor. The driver circuit output can be connected or directly connected to the first node, and a power source can be connected to both the driver and the second node.

Another example driver circuit includes a laser, a driver, and a power converter configured to maintain a float node at a potential greater than a ground node. The driver circuit also includes an electro-absorption optical modulator configured to modulate light output from the laser, where the modulator is coupled between the float node and an output of the driver.

Another example driver circuit includes a laser, an electro-absorption optical modulator configured to modulate light output from the laser, and a driver. The modulator is connected between a ground node and a negative potential. The driver has an output that is directly connected to the electro-absorption optical modulator through a capacitor. The driver circuit can also include a resistor connected in series with the electro-absorption optical modulator between the ground node and the negative potential. The driver circuit can also include a capacitor electrically coupled between the ground node and the negative potential, across a series arrangement of the electro-absorption optical modulator and the resistor.

The bias and driver circuits provide an alternative circuit arrangement for modulated lasers, including electro-absorption modulated lasers (EMLs), and are designed to operate without the use of ferrite beads or inductors in filter networks that would otherwise be coupled between the drivers and the modulators.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. In the drawings, like reference numerals designate like or corresponding, but not necessarily the same, elements throughout the several views.

FIG. 1 illustrates an example modulated laser bias and driver circuit according to various examples described herein.

FIG. 2 illustrates another example modulated laser bias and driver circuit according to various examples described herein.

FIG. 3 illustrates another example modulated laser bias and driver circuit according to various examples described herein.

### DETAILED DESCRIPTION

Optical interconnect solutions can rely upon a number of different laser diodes and laser diode modulation techniques. Two examples include directly modulated lasers (DMLs) and electro-absorption modulated lasers (EMLs). DMLs can use a distributed feedback structure with a diffraction grating in a waveguide for direct modulation. EMLs integrate a laser diode with an electro-absorption modulator (EAM) in a single device or chip. The laser diode can be operated as a continuous wave (CW) laser diode. The output of the laser diode can be modulated (e.g., turned on or off) by controlling the EAM, which either absorbs or transmits (e.g., passes) the laser light generated by the CW laser diode. The EAM can operate based on the Franz-Keldysh effect or the quantum-confined Stark effect, for example, where the absorption coefficient of a semiconductor material changes in response to an electric field, to quickly modulate the output intensity of the laser diode without mechanically or thermally varying the laser itself. EMLs can be preferred in some applications that demand higher speeds and longer distance transmissions.

Integrated driver and biasing circuitry can be relied upon to provide power to the lasers used in optical communication systems. Laser drivers are typically implemented as integrated circuits (ICs) using advanced CMOS, BiCMOS, SiGe, or other processes to achieve multi-gigahertz modulation bandwidths with low power dissipation and noise. The driver circuits are designed to provide precise control of modulation currents that drive DMLs, EAMs, EMLs, and other types of lasers and laser modulators. The driver circuits are designed are designed for high linearity, low jitter, and fast rise-and-fall times while maintaining impedance matching to minimize signal reflections along high-frequency transmission lines.

The driver and bias circuitry for modulated lasers has relied, in part, on bias chokes and filter networks to supply regulated and filtered power to laser diodes, modulators, and other components in integrated optical transmitters. Due to size, complexity, cost, and other factors, the bias chokes and filters can be unsuitable for integration with the remaining components of integrated optical transmitters in many cases. Those and other factors continue to drive the need for new bias and driver circuits for lasers, modulated lasers, and related integrated devices.

According to one example, a bias and driver circuit includes a laser, an electro-absorption optical modulator configured to modulate light output from the laser, a driver, and a power converter. The electro-absorption optical modulator is coupled between a float node and a ground node in the bias and driver circuit. The driver has an output coupled to the electro-absorption optical modulator, and the driver is configured to control the electro-absorption optical modulator to modulate the light output from the laser. The power converter is configured to maintain the float node at a potential greater than the ground node. The bias and driver circuits provide an alternative circuit arrangement for modulated lasers, including EMLs, and are designed to operate without the use of ferrite beads or inductors in filter networks that would otherwise be coupled between the drivers and the modulators.

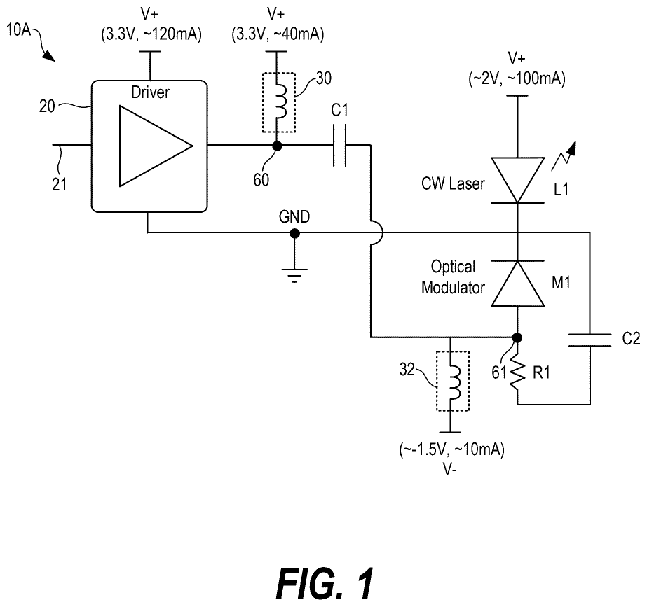

FIG. 1 illustrates an example modulated laser bias and driver circuit 10A (also “circuit 10A”) according to various examples described herein. The circuit 10A can be embodied in various ways, such as using discrete components, as an integrated circuit device formed on a substrate, or as a combination of discrete components and integrated devices. The circuit 10A is provided as a representative example of a driver and biasing circuit for an EML. The circuit 10A is not exhaustively illustrated in FIG. 1, and the circuit 10A can include additional components that are not shown. The circuit 10A can also omit certain components in some cases. It should also be appreciated that, while example electric potentials, currents, and other specifics may be described below and shown in the figures, the electric potentials and currents are described only as examples, and the bias and drive circuits can be operated using a range of different potentials and currents.

The circuit 10A includes a laser L1, an electro-absorption modulator M1 (also “modulator M1”), a driver 20, ferrite beads 30 and 32, capacitors C1 and C2, and a resistor R1 coupled in the electrical arrangement shown. The ferrite beads 30 and 32, capacitors C1 and C2, and resistor R1 are electrically coupled and operate as a type of filter network between the driver 20 and the modulator M1. The driver 20 receives an input signal 21 and generates a modulating drive signal as an output, which is provided to the filter network.

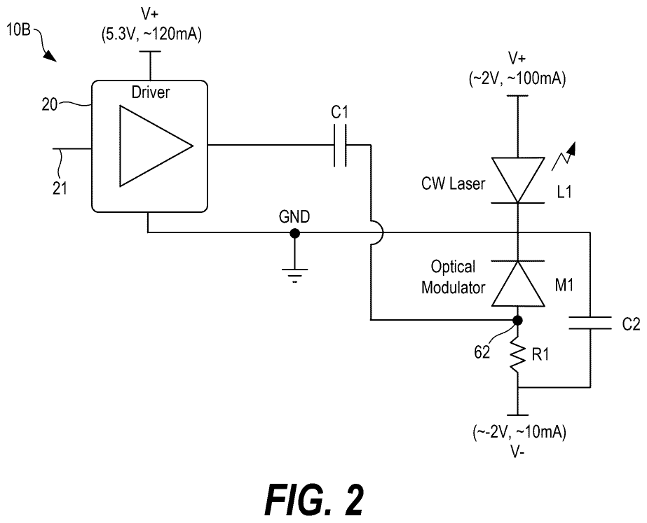

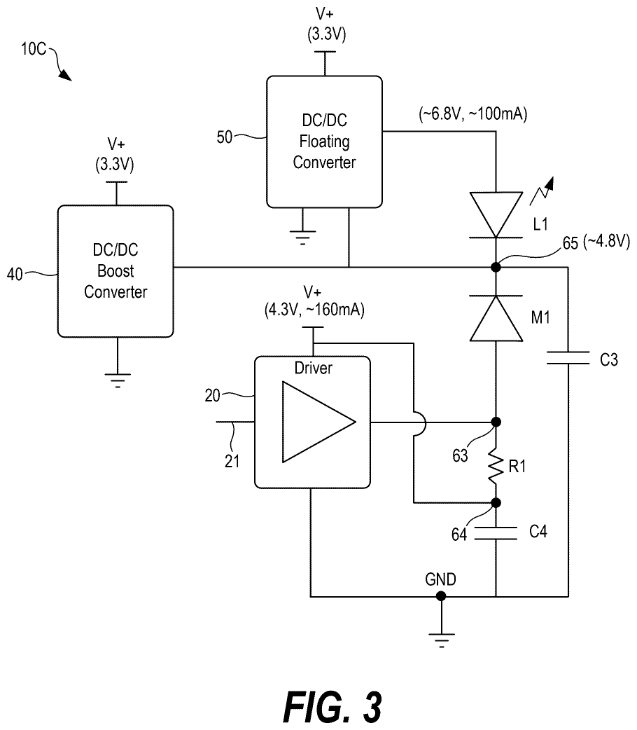

The laser L1 and the modulator M1 can be embodied as a single EML device, for example, and be integrated on a single semiconductor substrate or chip in some cases. The laser L1 can be embodied as a type of CW laser diode and is configured to generate a laser light output. The modulator M1 can be configured to modulate (e.g., transparently pass or opaquely block) the laser light output and generated by the laser L1. The modulator M1 can be embodied as a EAM and, based on a control potential supposed to the modulator M1 by the driver, the modulator M1 can either absorb or transmit the laser light generated by the laser L1. The modulator M1 can operate based on the Franz-Keldysh effect, the quantum-confined Stark effect, or a related semiconductor materials effect in which the absorption coefficient of the semiconductor material changes in response to an electric field or potential, to modulate the output intensity of the laser L1. While the modulator M1 is depicted using a diode symbol in FIG. 1 (and in FIGS. 2 and 3) according to some common conventions, it should be appreciated that the modulator M1 is not necessarily structured as or related to a diode device. Additionally, beyond CW laser diodes and electro-absorption modulators, the laser L1 and the modulator M1 can be embodied as other, related or equivalent, laser and optical absorption modulator devices.

In the arrangement shown in FIG. 1, the laser L1 is coupled between a power source and a ground node, referenced as “GND.” The laser L1 is coupled for forward biasing between a positive input voltage potential (e.g., ˜2V at 100 mA), which can be provided by a separate bias circuit (not shown), and the GND node. More particularly, the anode of the laser L1 is coupled to the positive input voltage potential, and the cathode of the laser L1 is coupled to the GND node. The modulator M1 is coupled between a negative input voltage potential (e.g., ˜1.5V at 10 mA) and the GND node. The biasing of the modulator M1 can be varied in the circuit 10A, however, based on the driver 20.

The driver 20 is configured to control the biasing and, thus, operation of the modulator M1. The modulator M1 is designed and configured to either pass or block the laser light output by the laser L1, to a varying extent for data communication. The driver 20 is configured to control the operation of the modulator M1 and thus the modulation of the light output by the laser L1 based on the biasing potential provided to M1 (e.g., based on the potential difference across the modulator M1). To that end, the driver 20 can generate and output at least two or more different output potentials over time which, in turn, control the biasing and operation of the modulator M1 in the configuration shown. The output of the driver 20 can be controlled based on a data signal provided as the input signal 21, among other input controls.

The ferrite beads 30 and 32 and capacitor C1 are electrically coupled between an output of the driver 20, at node 60, and the modulator M1, at node 61, in the example shown in FIG. 1. Additionally, the resistor R1 and the capacitor C2 are electrically coupled between the node 61 and the ground node GND. The ferrite bead 30 is electrically coupled between a positive voltage potential and the node 60, and the output of the driver 20 is also coupled to the node 60. One end of the capacitor C1 is coupled to the output of the driver 20 and the ferrite bead 30 at the node 60, and another end of the capacitor C1 is coupled to the ferrite bead 32, the optical modulator M1, and the resistor R1 at the node 61. One end of the ferrite bead 32 is electrically coupled to the node 61, and another end of the ferrite bead 32 is electrically coupled to a negative voltage potential. One end of the resistor R1 is electrically coupled to the node 61, and another end of the resistor R1 is electrically coupled to one end of the capacitor C2. The capacitor C2 is coupled between the resistor R1 and GND.

The ferrite beads 30 and 32 can be embodied as surface-mount components capable of suppressing high-frequency signals or noise. The ferrite beads 30 and 32 act as part of a bias-tee between the driver 20 and the modulator M1 in the implementation shown in FIG. 1, to suppress high-frequency noise (e.g., operate as broadband RF chokes) and prevent unwanted oscillations, among other purposes.

At certain data rates for the circuit 10A (e.g., 100 Gb/s), the ferrite beads 30 and 32 can operate suitably to suppress high-frequency noise (e.g., operate as broadband RF chokes), prevent unwanted oscillations, and serve related purposes. The ferrite beads 30 and 32 can also be manufactured at a reasonable cost. However, at high and increasingly higher data rates, the ferrite beads 30 and 32 are more costly to manufacture and, in some cases, may not exist or may not perform in a suitable way to suppress noise and achieve related objectives.

Given the increased need for higher data rates in optical communications, new circuit topologies and structures for modulated laser bias and driver circuits are needed. New biasing and driving circuits are particularly needed that can operate without the need for costly and complicated filter networks between driver circuits, biasing circuits, laser diodes, and optical modulators. Thus, one objective of the implementations described herein is to provide alternative biasing and driving circuits for modulated lasers, including EMLs, that are designed to operate without ferrite beads, such as the ferrite beads 30 and 32 shown in FIG. 1, and other types of inductors in filter networks.

FIG. 2 illustrates another example modulated laser bias and driver circuit 10B (also “circuit 10B”). The circuit 10B can be embodied in various ways, such as using discrete components, as an integrated circuit device formed on a substrate, or as a combination of discrete components and integrated devices. The circuit 10B is provided as a representative example of a driver and biasing circuit for an EML. The circuit 10B is not exhaustively illustrated in FIG. 2, and the circuit 10B can include additional components that are not shown. The circuit 10B can also omit certain components in some cases.

The circuit 10B includes the laser L1, the modulator M1, the driver 20, capacitors C1 and C2, and the resistor R1 coupled in the electrical arrangement shown. The laser L1 and the modulator M1 can be embodied as a single EML device integrated on a single semiconductor substrate or chip in some cases. The laser L1 can be embodied as a type of CW laser diode and is configured to generate a laser light output. The modulator M1 can be configured to modulate (e.g., transparently pass or opaquely block) the laser light output and generated by the laser L1. Beyond CW laser diodes and electro-absorption modulators, the laser L1 and the modulator M1 can be embodied as other, related or equivalent, laser and optical absorption modulator devices.

In the arrangement shown in FIG. 2, the laser L1 is coupled between a power source and the GND node. The laser L1 is coupled for forward biasing between a positive input voltage potential (e.g., ˜2V at 100 mA), which can be provided by a separate bias circuit (not shown), and the GND node. More particularly, the anode of the laser L1 is coupled to the positive input voltage potential, and the cathode of the laser L1 is coupled to the GND node.

The modulator M1 is coupled between the GND node and a negative input voltage potential (e.g., ˜2V at 10 mA), through the resistor R1, and also to the output of the driver 20. A first end of the modulator M1 is directly coupled to the GND node, and a second end of the modulator M1 is directly coupled to the node 62. A first end of the resistor R1 is also directly coupled to the node 62. A second end of the resistor R1 is coupled to the negative input voltage potential. Thus, the modulator M1 and the resistor R1 are electrically coupled in series between the GND node and a negative potential in the circuit 10B.

The output of the driver 20 is coupled to the node 62 between the modulator M1 and the resistor R1, through the capacitor C1. The output of the driver 20 is directly coupled to a first end of the capacitor C1, and a second end of the capacitor C1 is directly coupled to the node 62. The extent of the electro-absorption provided by the modulator M1 can be controlled in the circuit 10B based on the output of the driver 20 and, more particularly, the change in potential at the node 60 based on the output of the driver 20.

The driver 20 is configured to control the potential(s) at the node 60 over time and, thus, operation of the modulator M1. The modulator M1 is designed and configured to either pass or block the laser light output by the laser L1, to a varying extent for data communication. The driver 20 is configured to control the operation of the modulator M1 based on the biasing of the modulator M1 (i.e., based on the potential difference across the modulator M1). In that sense, the driver 20 can output at least two or more different output potentials which, in turn, control the biasing at the node 60 and the operation of the modulator M1 in the configuration shown. The output of the driver 20 can be controlled based on a data signal provided as the input signal 21, among possibly other input controls.

The driver 20 in FIG. 2 is similar to that in FIG. 1, but the driver 20 is supplied by a power source of a greater potential in FIG. 2 as compared to FIG. 1. In FIG. 1, the driver 20 is supplied by an example power source of 3.3V at 120 mA. In FIG. 2, the driver 20 is supplied by an example power source of 5.3V at 120 mA. Additionally, the modulator M1 is tied to a greater negative potential through the resistor R1 in FIG. 2 as compared to FIG. 1. In FIG. 1, the resistor R1 is coupled between the optical modulator M1 at the node 61 and the negative potential of about −1.5V. In FIG. 2, the resistor R1 is coupled between the optical modulator M1 at the node 62 and a negative potential of about −2V. In other examples, the resistor R1 can be coupled between the optical modulator M1 at the node 62 and a negative potential of about −2.1V, −2.2V, −2.3V, −2.4V, −2.4V, −2.5V or a greater negative potential. The resistor R1 can also be coupled between the optical modulator M1 at the node 62 and an even greater negative potential, such as −2.5V, −3.0V, −3.5V, −4.0V, −4.5V, −5.0V, or a greater negative potential.

The ferrite beads 30 and 32 of the circuit 10A shown in FIG. 1 are omitted from the circuit 10B shown in FIG. 2, due in part to the altered biasing and circuit arrangement relied upon in FIG. 2. The circuit 10A does not include or rely upon any ferrite beads, inductors, or filter network including inductors coupled between the output of the driver 20 and the optical modulator M1. Instead, the output of the driver 20 is directly coupled to the modulator M1 through the capacitor C1. By supplying the driver 20 with a power source of greater potential and by biasing the modulator M1 with a greater negative potential through the resistor R1, the need for ferrite beads can be mitigated, and no ferrite beads are used in the circuit 10B.

FIG. 3 illustrates another example modulated laser bias and driver circuit 10C (also “circuit 10C”) according to various examples described herein. The circuit 10C can be embodied in various ways, such as using discrete components, as an integrated circuit device formed on a substrate, or as a combination of discrete components and integrated devices. The circuit 10C is provided as a representative example of a driver and biasing circuit for an EML. The circuit 10C is not exhaustively illustrated in FIG. 3, and the circuit 10C can include additional components that are not shown. The circuit 10C can also omit certain components in some cases.

The circuit 10C includes the laser L1, the modulator M1, the driver 20, a DC/DC boost converter 40, a DC/DC floating converter 50, the resistor R1, and capacitors C3 and C4 coupled in the electrical arrangement shown. Both the DC/DC boost converter 40 and the DC/DC floating converter 50 (also “power converter 40,” “power converter 50,” and “power converters 40 and 50”) can be embodied as power converters or integrated power converter circuits. The laser L1 and the modulator M1 can be embodied as a single EML device integrated on a single semiconductor substrate or chip in some cases. The laser L1 can be embodied as a type of CW laser diode and is configured to generate a laser light output. The modulator M1 can be configured to modulate (e.g., transparently pass or opaquely block) the laser light output and generated by the laser L1. Beyond CW laser diodes and electro-absorption modulators, the laser L1 and the modulator M1 can be embodied as other, related or equivalent, laser and optical absorption modulator devices.

The circuit 10C includes a float node 65, and both the laser L1 and the modulator M1 are electrically coupled to the float node 65. As compared to the circuits 10A and 10B shown in FIGS. 1 and 2, where both the laser L1 and the modulator M1 are electrically coupled at one end to the GND node, the laser L1 and the modulator M1 are biased with respect to the electric potential at the float node 65 in the circuit 10C shown in FIG. 3. The output of the DC/DC boost converter 40 is electrically coupled to the float node 65, and the DC/DC boost converter 40 is configured to set a voltage potential at the float node 65 based on the output. Thus, the electric potential at the float node 65 is regulated by the DC/DC boost converter 40. The DC/DC boost converter 40 is configured to set and maintain the float node 65 at a potential greater than the GND node. As one example, the DC/DC boost converter 40 regulates the float node 65 to a potential of ˜4.8V, although the DC/DC boost converter 40 can regulate the float node 65 to other potentials, as discussed below.

The DC/DC floating converter 50 is configured to generate a bias current for the laser L1. The DC/DC floating converter 50 is configured to generate the bias current at a potential larger than the potential on the float node 65, using the potential on the float node 65 as a reference potential. In the example shown in FIG. 3, the DC/DC floating converter 50 generates a bias current of ˜6.8V at 100 mA as power supply for the laser L1. The DC/DC floating converter 50 can generate the bias current at other potentials for the laser L1. The DC/DC floating converter 50 can be embodied as a floating, transformer-based DC/DC converter. Both the DC/DC boost converter 40 and the DC/DC floating converter 50 can operate with an input supply, such as the 3.3V input supply rail shown in FIG. 3, and other supply voltages can be relied upon.

The laser L1 is coupled between an output power source provided by the DC/DC floating converter 50 and the float node 65 in the circuit 10C. The laser L1 is forward biased for operation between the positive voltage potential output by the DC/DC floating converter 50 and the positive voltage potential output by the DC/DC boost converter 40 to the float node 65. The output of the DC/DC floating converter 50 can be about 6.8V (e.g., ˜6.8V at 100 mA) in one example, and the output of the DC/DC boost converter 40 can be about ˜4.8V in the example shown. Thus, the potential difference between the converters 40 and 50 is about 2V in the example shown in FIG. 3, and the laser L1 is forward biased by about 2V. The converters 40 and 50 can also be configured for a greater or smaller potential difference to forward bias the laser L1. As examples, the DC/DC floating converter 50 can be configured to generate an output voltage potential that is 1.5V, 1.6V, 1.7V, 1.8V, 1.9V, 2.0V, 2.1V, 2.2V, 2.3V, 2.4V, 2.5V or greater than the output potential of the DC/DC boost converter 40 at the float node 65. Also, the DC/DC boost converter 40 can be configured to generate an output voltage potential at the float node 65 that is between 2-8V, for example, and at any increment of 0.1V or 0.05V including and between 2-8V.

The modulator M1 is coupled between the float node 65 and the GND node through the resistor R1 and the capacitor C4. Thus, the circuit 10C includes the modulator M1, the resistor R1, and the capacitor C4 electrically coupled in a series arrangement between the float node 65 and the GND node. The series arrangement includes a first node 63 between the modulator M1 and the resistor R1 and a second node 64 between the resistor R1 and the capacitor C4.

The modulator M1 can be controlled in the circuit 10C based on the output of the driver 20. More particularly, the modulator M1 is configured to modulate the light output from the laser L1 based on the based on the output of the driver 20. One end of the modulator M1 is directly coupled to the float node 65, and another end of the modulator M1 is directly coupled to the node 63. The output of the driver 20 is also directly coupled to the node 63 in the example shown. One end of the resistor R1 is directly coupled to the node 63, and another end of the resistor R1 is coupled to the capacitor C4 at the node 64. One end of the capacitor C4 is coupled to the resistor R1 at the node 64, and another end of the capacitor C4 is coupled to GND. One end of the capacitor C3 is coupled to the float node 65, and another end of the capacitor C3 is coupled to GND. The capacitor C3 is coupled across the series-connected string of the modulator M1, the resistor R1, and the capacitor C4.

In the circuit 10C shown in FIG. 3, the modulator M1 is biased between the potential at the float node 65 and the output potential provided at the output of the driver 20. The driver 20 in FIG. 3 is similar to those shown in FIGS. 1 and 2, but the driver 20 is supplied by a power source of a different potential in FIG. 3 as compared to FIGS. 1 and 2. The driver 20 in FIG. 3 is supplied by a power source having a potential of ˜4.3V at 160 mA. The power source provided to the driver 20 is also electrically coupled to the node 64, between the capacitor C4 and the resistor R1.

The driver 20 is configured to control and adjust the biasing of the modulator M1. The driver 20 can adjust the potential across the modulator M1 so that the modulator M1 is forward biased in some cases or, at least, reverse biased to a lesser extent (i.e., less than the −0.5V reverse bias of 4.3V-4.8V). The driver 20 can output two or more different output potentials which, in turn, control the biasing and operation of the modulator M1 in the configuration shown. The output of the driver 20 can be controlled based on a data signal provided as the input signal 21, among possibly other input controls.

The ferrite beads 30 and 32 of the circuit 10A shown in FIG. 1 can be omitted from the circuit 10C shown in FIG. 3, due to the altered biasing arrangement relied upon in the circuit 10C. The need for ferrite beads can be mitigated in the arrangement shown in FIG. 3, and no ferrite beads are used in the circuit 10C. More particularly, no ferrite beads or inductors are used in any filter network between the driver 20 and the modulator M1. Instead, the output of the driver 20 is directly coupled to the modulator M1.

The active devices described herein can be formed using any suitable semiconductor materials, including silicon germanium (SiGe), group III-V semiconductor materials, and other semiconductor materials and related and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them.

When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. A bias and driver circuit comprising:
a laser;
an electro-absorption optical modulator configured to modulate light output from the laser, the electro-absorption optical modulator being coupled between a float node and a ground node in the bias and driver circuit;
a driver having an output coupled to the electro-absorption optical modulator, the driver being configured to control the electro-absorption optical modulator; and
a power converter configured to maintain the float node at a potential greater than the ground node.

2. The bias and driver circuit according to claim 1, wherein the laser is coupled and biased between the float node, at one end of the laser, and an output of a second power converter at another end of the laser.

3. The bias and driver circuit according to claim 2, wherein:
the power converter comprises a DC/DC boost converter having an output coupled to the float node; and
the second power converter comprises a DC/DC floating converter coupled between the float node and the output of the second power converter.

4. The bias and driver circuit according to claim 3, wherein the output of the DC/DC boost converter sets a voltage potential at the float node.

5. The bias and driver circuit according to claim 1, wherein the output of the driver is directly coupled to the electro-absorption optical modulator.

6. The bias and driver circuit according to claim 1, wherein the driver is configured to control the electro-absorption optical modulator based on drive potentials greater than the ground node and less than the float node.

7. The bias and driver circuit according to claim 1, further comprising a resistor and a capacitor, wherein the electro-absorption optical modulator, the resistor, and the capacitor are electrically coupled in a series arrangement between the float node and the ground node in the bias and driver circuit.

8. The bias and driver circuit according to claim 7, further comprising a second capacitor coupled in parallel with the series arrangement of the electro-absorption optical modulator, the resistor, and the capacitor between the float node and the ground node in the bias and driver circuit.

9. The bias and driver circuit according to claim 7, wherein:
the series arrangement comprises a first node between the electro-absorption optical modulator and the resistor and a second node between the resistor and the capacitor;
an output of the driver circuit is coupled to the first node; and
a power source is coupled to the driver and the second node.

10. A driver circuit comprising:
a laser;
a driver;
a power converter configured to maintain a float node in the driver circuit at a potential greater than a ground node in the driver circuit; and
an electro-absorption optical modulator configured to modulate light output from the laser, the electro-absorption optical modulator being coupled between the float node and an output of the driver.

11. The driver circuit according to claim 10, wherein the laser is coupled and biased between the float node, at one end of the laser, and an output of a second power converter at another end of the laser.

12. The driver circuit according to claim 11, wherein:
the power converter comprises a DC/DC boost converter having an output coupled to the float node; and
the second power converter comprises a DC/DC floating converter coupled between the float node and the output of the second power converter.

13. The driver circuit according to claim 10, wherein the output of the driver is directly coupled to the electro-absorption optical modulator.

14. The driver circuit according to claim 10, wherein the driver is configured to control the electro-absorption optical modulator based on drive potentials greater than the ground node and less than the float node.

15. The driver circuit according to claim 10, further comprising a resistor and a capacitor, wherein the electro-absorption optical modulator, the resistor, and the capacitor are electrically coupled in series between the float node and the ground node in the driver circuit.

16. The driver circuit according to claim 10, wherein the electro-absorption optical modulator, a resistor, and a capacitor are electrically coupled in a series arrangement between the float node and the ground node in the driver circuit.

17. The driver circuit according to claim 16, wherein:
the series arrangement comprises a first node between the electro-absorption optical modulator and the resistor and a second node between the resistor and the capacitor;
an output of the driver circuit is coupled to the first node; and
a power source is coupled to the driver and the second node.

18. A driver circuit comprising:
a laser;
an electro-absorption optical modulator configured to modulate light output from the laser, the electro-absorption optical modulator being coupled between a ground node and a negative potential; and
a driver having an output directly coupled to the electro-absorption optical modulator through a capacitor.

19. The driver circuit according to claim 18, further comprising a resistor, wherein the electro-absorption optical modulator and the resistor are electrically coupled in a series arrangement between the ground node and a negative potential.

20. The driver circuit according to claim 19, further comprising a capacitor electrically coupled between the ground node and the negative potential, across the series arrangement of the electro-absorption optical modulator and the resistor.
